(19) United States
(12) Patent Application Publication
(10) Pub. No.: US 2025/0362573 A1
(43) Pub. Date: Nov. 27, 2025

(54) OPTICAL ENGINE MODULE AND PROJECTION DEVICE

(71) Applicant: Coretronic Corporation, Hsin-Chu (TW)

(72) Inventor: Wei-Min Chien, Hsin-Chu (TW)

(73) Assignee: Coretronic Corporation, Hsin-Chu (TW)

(21) Appl. No.: 19/215,335

(22) Filed: May 22, 2025

(30) Foreign Application Priority Data
May 23, 2024 (CN) 202410644382.5

(51) Int. Cl. G03B 21/16; H05K 7/20

(52) U.S. Cl. CPC G03B 21/16; H05K 7/20145; H05K 7/20172

(57) ABSTRACT

A projection device includes an optical engine module including a housing having an accommodating space, a transmissive light valve disposed in the accommodating space and located between a focusing lens and an optical sheet, and a fan module disposed in the housing and having a first air outlet and a second air outlet is provided. The accommodating space is divided into a first inner circulation zone and a second inner circulation zone. The focusing lens is disposed in the first inner circulation zone, and a first gap is formed between the focusing lens and the transmissive light valve. The optical sheet is disposed in the second inner circulation zone, and a second gap is formed between the transmissive light valve and the optical sheet. The fan module provides a first airflow to the first gap and a second airflow to the second gap.

### CROSS-REFERENCE TO RELATED APPLICATION

This application claims the priority benefit of China application serial no. 202410644382.5 filed on May 23, 2024. The entirety of the above-mentioned patent application is hereby incorporated by reference herein and made a part of this specification.

### BACKGROUND

### Technical Field

The disclosure relates to an optical device, and particularly relates to an optical engine module and a projection device.

### Description of Related Art

Since One LCD panel projector has low optical efficiency, it generates heat inside an optical engine. The prior art utilizes an open optical engine design to introduce cold air from the outside to flow through the optical engine to cool the LCD panel. However, this method easily allows external dust to enter the interior of the optical engine to contaminate optical components, thereby causing problems such as low reliability, short service life and reduced projection quality. In order to avoid dust pollution, a closed optical engine design is currently adopted together with a heatsink penetrating the inside and outside of the optical engine, so that the heat inside the optical engine may be transferred to the outside of the optical engine through the heatsink, and a system fan is adopted to implement heat exchange. Compared with the open optical engine design, the closed optical engine design cannot remove the heat of the LCD panel by direct convecting with the outside of the optical engine, the heat must be first transferred from the inside of the optical engine to the outside of the optical engine through conduction of the heatsink, so that the efficiency is lower, and a larger volume is required to achieve a same heat dissipation effect. In addition, although the closed optical engine design mitigates the problem of dust intrusion, since a wind flow temperature cannot be maintained as low as the outside low temperature like the open optical engine, a brightness of the closed optical engine cannot be the same as a brightness of the open optical engine, which means that the maximum brightness of the projector is limited.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

An embodiment of the disclosure provides an optical engine module for connecting to a lens module. The optical engine module includes a housing, a transmissive light valve, a focusing lens, an optical sheet, and a fan module. The housing has an accommodating space and is connected to the lens module. The transmissive light valve is disposed in the accommodating space, wherein the transmissive light valve divides the accommodating space into a first inner circulation zone and a second inner circulation zone. The focusing lens is disposed in the first inner circulation zone, and a first gap is formed between the focusing lens and the transmissive light valve. The optical sheet is disposed in the second inner circulation zone, and the transmissive light valve is located between the focusing lens and the optical sheet. A second gap is formed between the transmissive light valve and the optical sheet. The fan module is disposed in the housing. The fan module has a first air outlet and a second air outlet. The fan module provides a first airflow to the first gap through the first air outlet. The fan module provides a second airflow to the second gap through the second air outlet. A normal direction of the first air outlet is a first direction, a normal direction of the second air outlet is a second direction, and the first direction is different from the second direction.

An embodiment of the disclosure provides a projection device including a light source module, an optical engine module and a lens module. The light source module is configured to provide an illumination beam. The optical engine module includes a housing, a transmissive light valve, a focusing lens, an optical sheet, and a fan module. The housing has an accommodating space. The transmissive light valve is disposed in the accommodating space, and is located in a transmission path of the illumination beam, and is configured to convert the illumination beam into an image beam. The transmissive light valve divides the accommodating space into a first inner circulation zone and a second inner circulation zone. The focusing lens is disposed in the first inner circulation zone, and a first gap is formed between the focusing lens and the transmissive light valve. The optical sheet is disposed in the second inner circulation zone, and the transmissive light valve is located between the focusing lens and the optical sheet. A second gap is formed between the transmissive light valve and the optical sheet. The fan module is disposed in the housing. The fan module has a first air outlet and a second air outlet. The fan module provides a first airflow to the first gap through the first air outlet. The fan module provides a second airflow to the second gap through the second air outlet. A normal direction of the first air outlet is a first direction, a normal direction of the second air outlet is a second direction, and the first direction is different from the second direction. The lens module is connected to the housing, and is disposed in a transmission path of the image beam, and a part of the lens module is disposed in the housing. The lens module is configured to project the image beam out of the projection device.

Other objectives, features and advantages of the disclosure will be further understood from the further technological features disclosed by the embodiments of the disclosure wherein there are shown and described preferred embodiments of this disclosure, simply by way of illustration of modes best suited to carry out the disclosure.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a schematic perspective view of a projection device according to an embodiment of the disclosure.

FIG. 1B is another schematic perspective view of the projection device of FIG. 1A.

FIG. 1C is a view of a transmissive light valve in the projection device of FIG. 1A.

FIG. 2A to FIG. 2C are schematic diagrams of heat exchange modules in various embodiments of the disclosure.

FIG. 3A is a schematic three-dimensional view of a projection device according to another embodiment of the disclosure.

FIG. 3B is a schematic view of the projection device of FIG. 3A.

FIG. 3C is another schematic view of the projection device of FIG. 3A.

FIG. 3D is a schematic cross-sectional view along a line I-I of FIG. 3B.

FIG. 3E is a schematic cross-sectional view along a line II-II of FIG. 3C.

FIG. 3F is a schematic diagram of relative positions of a fan module, a first gap and a second gap in FIG. 3A.

### DESCRIPTION OF THE EMBODIMENTS

In the following detailed description of the preferred embodiments, reference is made to the accompanying drawings which form a part hereof, and in which are shown by way of illustration specific embodiments in which the disclosure may be practiced. In this regard, directional terminology, such as “top,” “bottom,” “left,” “right,” “front,” “back,” etc., is used with reference to the orientation of the Figure(s) being described. The components of the disclosure can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the disclosure. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

The disclosure provides an optical engine module, which has a great heat dissipation effect.

The disclosure further provides a projection device, which includes the above-mentioned optical engine module and has great imaging quality.

Additional aspects and advantages of the disclosure will be set forth in the description of the techniques disclosed in the disclosure.

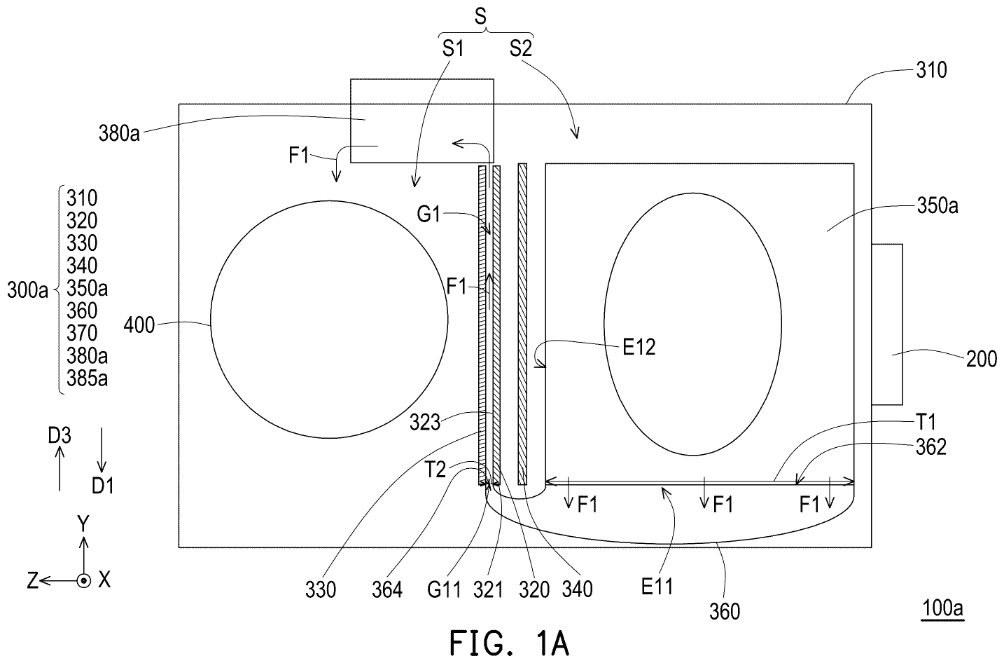

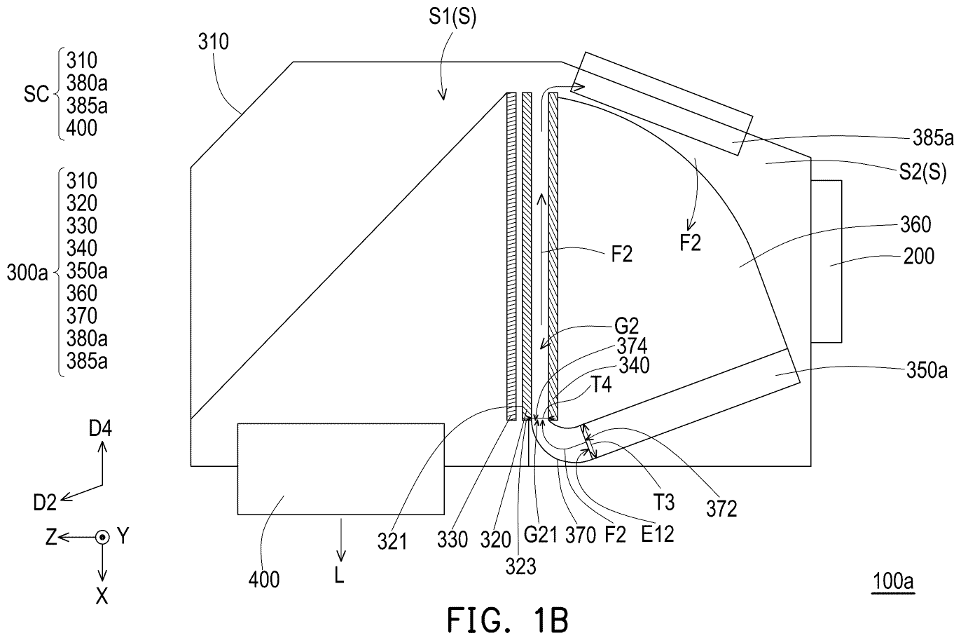

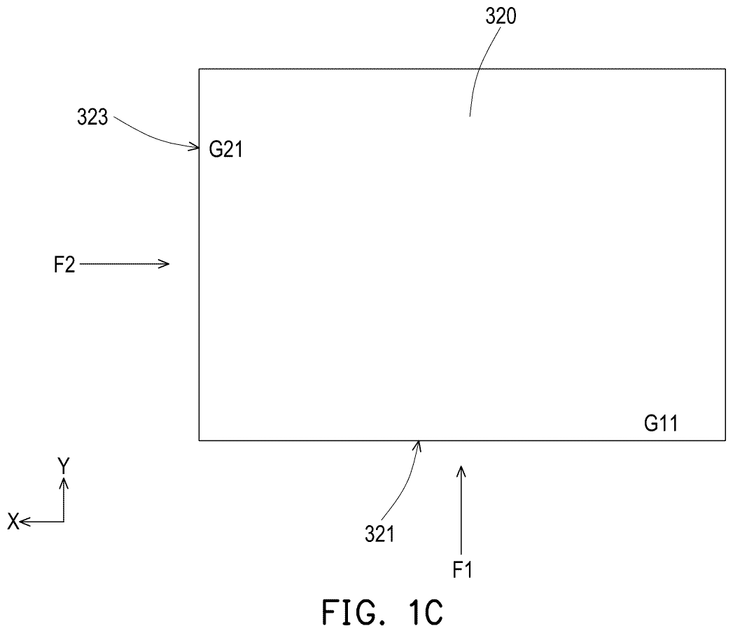

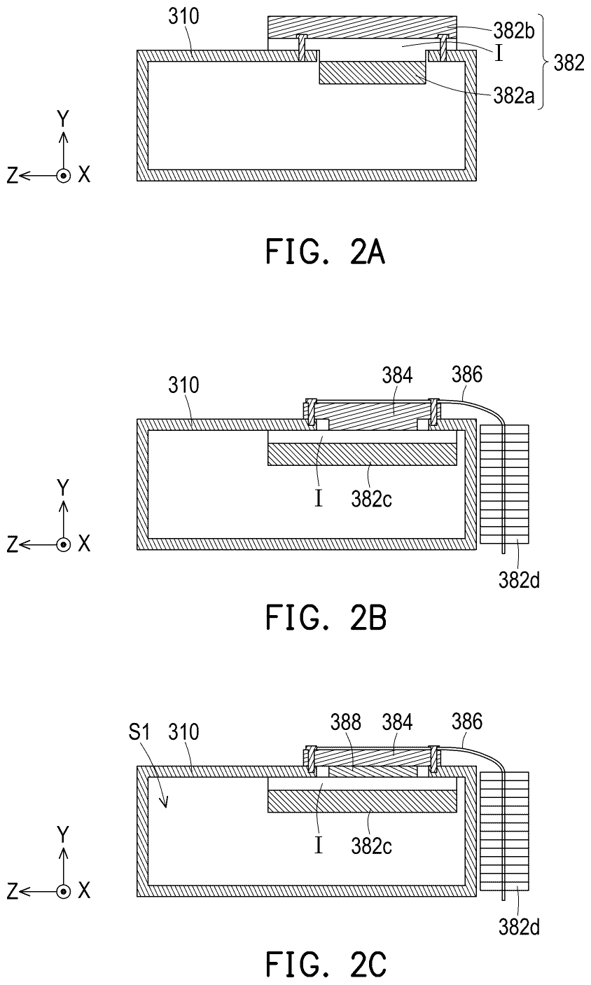

FIG. 1A is a schematic perspective view of a projection device according to an embodiment of the disclosure. FIG. 1B is another schematic perspective view of the projection device of FIG. 1A. FIG. 1C is a view of a transmissive light valve in the projection device of FIG. 1A. FIG. 2A to FIG. 2C are schematic diagrams of heat exchange modules in various embodiments of the disclosure.

Referring to FIG. 1A and FIG. 1B at the same time, in the embodiment, a projection device 100a includes a light source module 200, an optical engine module 300a, and a lens module 400. The light source module 200 is configured to provide an illumination beam. The optical engine module 300a is disposed in a transmission path of the illumination beam to convert the illumination beam into an image beam. The lens module 400 is disposed in a transmission path of the image beam to project the image beam out of the projection device 100a. A reflective element (such as a reflector) may be set (in the optical path) between the optical engine module 300a and the lens module 400 to guide the image beam from the optical engine module 300a to the lens module 400.

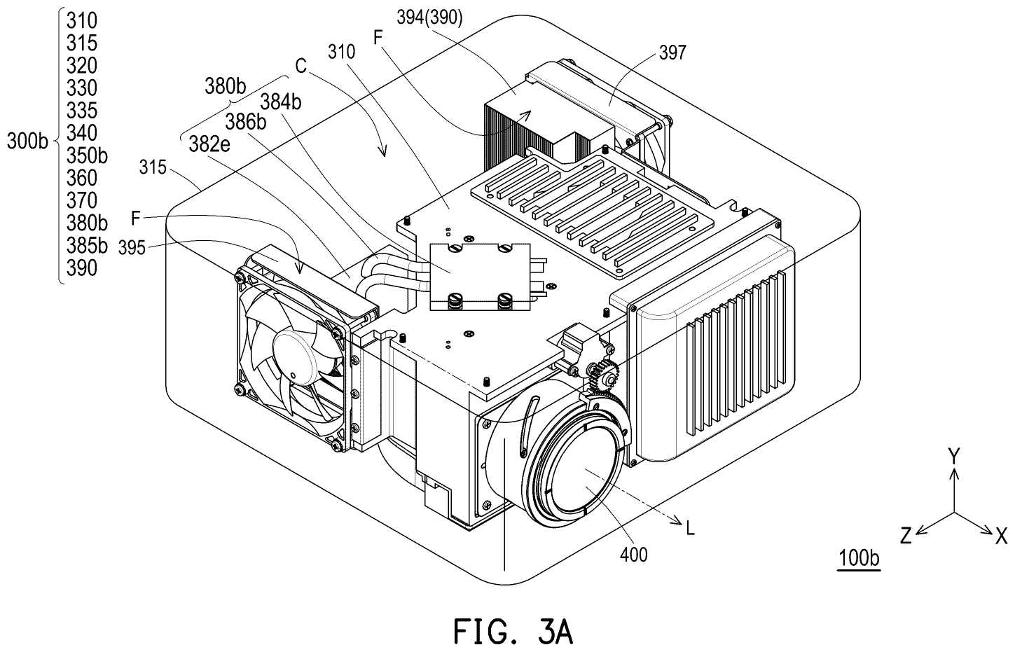

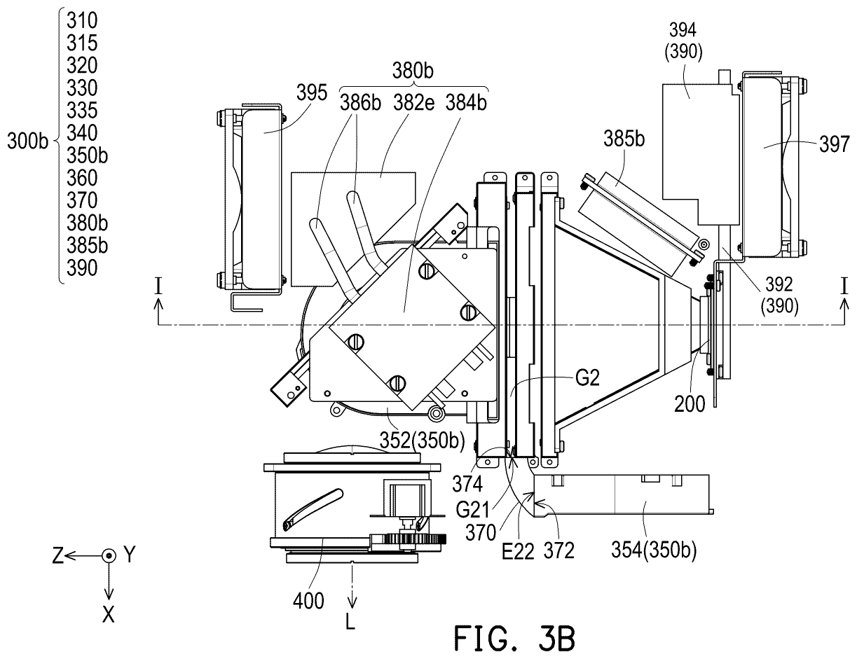

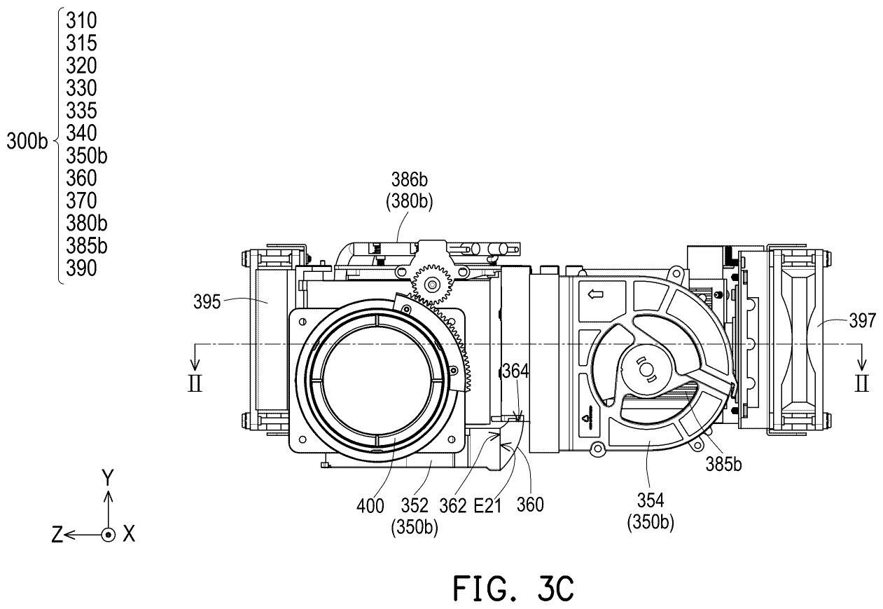

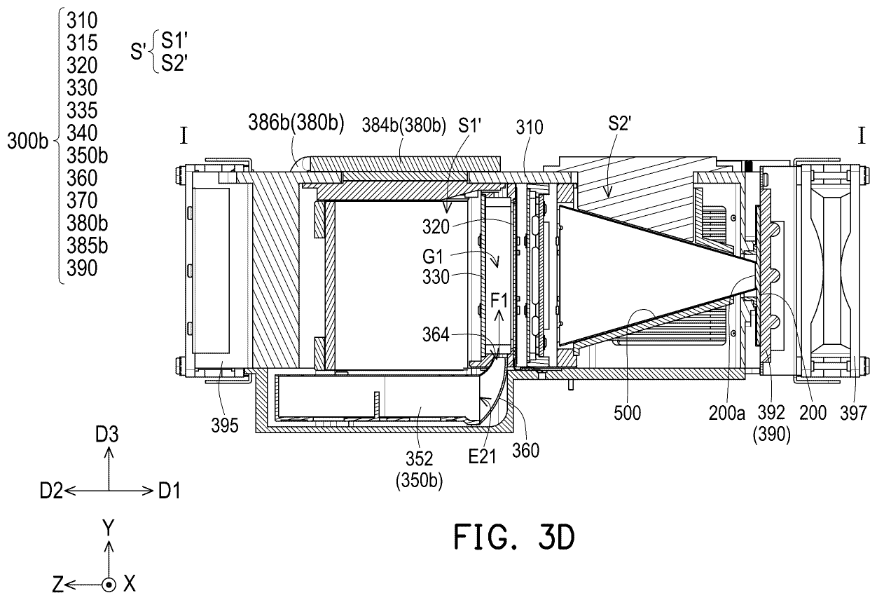

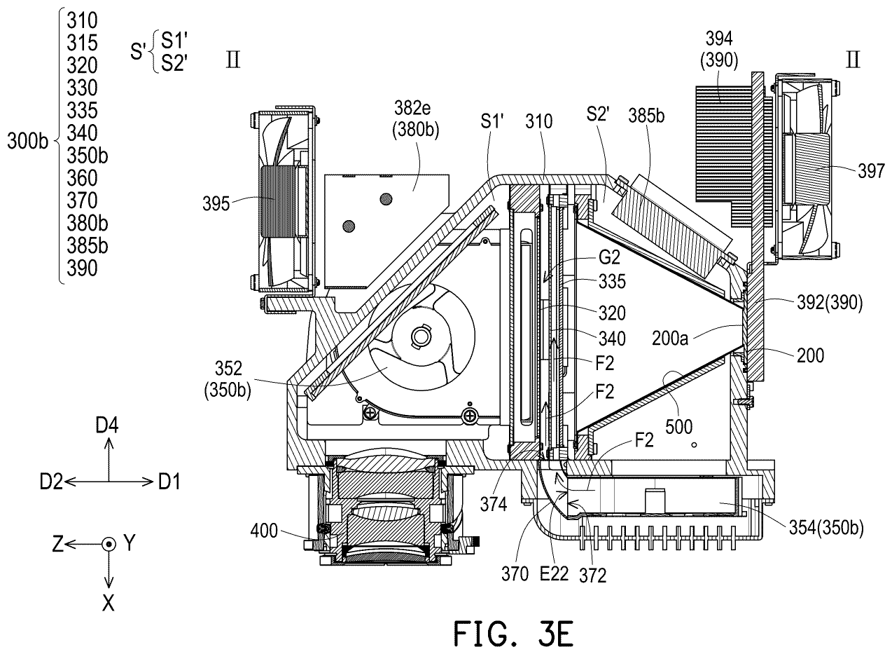

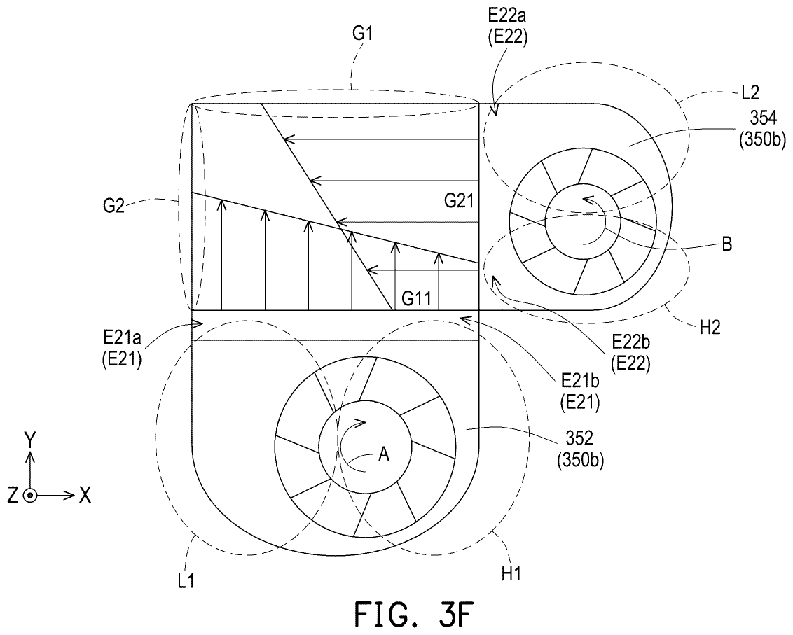

In an embodiment, the light source module 200 may include one or a plurality of light-emitting elements 200a (shown in FIG. 3D), wherein the light-emitting element is, for example, one or a plurality of laser diodes (LD), one or a plurality of light-emitting diodes (LED), or a combination of the above two light sources. Specifically, any light source that meets a volume requirement in an actual design may be used as an implementation, and the disclosure is not limited thereto. In an embodiment, the optical engine module 300a may include a transmissive light valve 320, such as a transparent liquid crystal panel, an electro-optical modulator, a magneto-optical modulator, an acousto-optic modulator (AOM), etc. Detailed steps and implementation methods of the method for the transmissive light valve 320 of the optical engine module 300a to convert the illumination beam into the image beam may be sufficiently taught, suggested and implemented by the common knowledge in the relevant technical field, so that details thereof are not repeated. The lens module 400, for example, includes a combination of one or a plurality of optical lenses with refractive power, such as various combinations of non-planar lenses such as a biconcave lens, a biconvex lens, a concavo-convex lens, a convexo-concave lens, a plano-convex lens, a plano-concave lens, etc. In an embodiment, the lens module 400 may also include a planar optical lens to convert the image beam from the optical engine module 300a into a projection beam through a reflective or transmissive manner and project the projection beam out of the projection device 100a. The pattern and type of the lens module 400 are not limited by the disclosure.

Further, referring to FIG. 1A and FIG. 1B at the same time, in the embodiment, the optical engine module 300a includes a housing 310, a transmissive light valve 320, a focusing lens 330, an optical sheet 340, and a fan module 350a. The housing 310 has an accommodating space S. The transmissive light valve 320 is disposed in the accommodating space S and is located in the transmission path of the illumination beam to convert the illumination beam into the image beam. The transmissive light valve 320 divides the accommodating space S into a first inner circulation zone S1 (for example, at a side of a light emitting surface of the transmissive light valve 320) and a second inner circulation zone S2 (for example, at a side of a light incident surface of the transmissive light valve 320). The focusing lens 330 is disposed in the first inner circulation zone S1, and a first gap G1 is formed between the focusing lens 330 and the transmissive light valve 320 (the first gap G1 is, for example, located between the light emitting surface of the transmissive light valve 320 and the focusing lens 330). The focusing lens 330 is, for example, a Fresnel lens. The optical sheet 340 is disposed in the second inner circulation zone S2, and the transmissive light valve 320 is located between the focusing lens 330 and the optical sheet 340. A second gap G2 is formed between the transmissive light valve 320 and the optical sheet 340 (the second gap G2 is, for example, located between the light incident surface of the transmissive light valve 320 and the optical sheet 340). The fan module 350a is disposed in the housing 310. The fan module 350a has a first air outlet E11 and a second air outlet E12. The fan module 350a provides a first airflow F1 from the first air outlet E11 to the first gap G1 (shown in FIG. 1A), and the fan module 350a provides a second airflow F2 from the second air outlet E12 to the second gap G2 (shown in FIG. 1B). A normal direction of the first air outlet E11 is a first direction D1, a normal direction of the second air outlet E12 is a second direction D2, and the first direction D1 is different from the second direction D2. The lens module 400 is connected to the housing 310, and a part of the lens module 400 is disposed in the housing 310 (as shown in FIG. 1B).

The optical sheet 340 of the embodiment may be, for example, an optical lens or a polarizing sheet, but the disclosure is not limited thereto. In an embodiment, when the illumination beam incident to the optical engine module 300a is polarized light, the optical sheet 340 may be, for example, an optical lens (such as a Fresnel lens) to collimate the illumination beam into parallel light. In an embodiment, if the illumination beam is non-polarized light, a polarizer may be added between the optical lens and the transmissive light valve 320 to polarize the illumination beam, and the optical sheet 340 here is the polarizer. In the embodiment, the optical sheet 340 is a polarizer, and a second gap G2 is formed between the optical sheet 340 and the transmissive light valve 320.

As shown in FIG. 1A and FIG. 1B, the fan module 350a of the embodiment includes a single cooling fan with two air outlets, wherein the cooling fan may be, for example, a blower fan, but the disclosure is not limited thereto. Here, the first direction D1 (for example, a direction opposite to the Y direction) is perpendicular (or an included angle there between is greater than 75 degrees and less than 105 degrees) to an optical axis direction L (for example, a direction parallel to the X direction) of the lens module 400.

Furthermore, the optical engine module 300a of the embodiment may also include a first air guide duct 360 (shown in FIG. 1A) and a second air guide duct 370 (shown in FIG. 1B). The first air guide duct 360 is a curved tube and has a first port 362 and a second port 364. The first port 362 is connected to the first air outlet E11, i.e., the first air outlet E11 is connected to an opening of the first air guide duct 360, and the second port 364 is connected to a first inlet terminal G11 of the first gap G1. Here, as shown in FIG. 1A, a diameter T1 of the first port 362 may be larger than a diameter T2 of the second port 364, thereby reducing a flow resistance on the air output by the fan module 350a that turns and enters the first gap G1 of the smaller channel through the tapered diameter design, so as to effectively reduce the flow resistance. The second air guide duct 370 is a curved pipe and has a third port 372 and a fourth port 374. The third port 372 is connected to the second air outlet E12, i.e., the second air outlet E12 is connected to an opening of the second air guide duct 370, and the fourth port 374 is connected to a second inlet terminal G21 of the second gap G2. Here, as shown in FIG. 1B, a diameter T3 of the third port 372 may be larger than a diameter T4 of the fourth port 374, thereby reducing a flow resistance on the air output by the fan module 350a that turns and enters the second gap G2 of the smaller channel through the tapered diameter design, so as to effectively reduce the flow resistance.

More specifically, one of the second port 364 of the first air guide duct 360 and the fourth port 374 of the second air guide duct 370 is located at one side of a long side 321 (referring to FIG. 1C) of the transmissive light valve 320. The other of the second port 364 of the first air guide duct 360 and the fourth port 374 of the second air guide duct 370 is located at one side of a short side 323 (referring to FIG. 1C) of the transmissive light valve 320. The long side 321 of the transmissive light valve 320 is connected to the short side 323. Here, the second port 364 of the first air guide duct 360 is located at the side of the long side 321 of the transmissive light valve 320, and the fourth port 374 of the second air guide duct 370 is located at the side of the short side 323 of the transmissive light valve 320. A normal direction of the second port 364 of the first air guide duct 360 is a third direction D3 (for example, a direction parallel to the Y direction). A normal direction of the fourth port 374 of the second air guide duct 370 is a fourth direction D4 (for example, a direction opposite to the X direction). The third direction D3 is different from the first direction D1. The fourth direction D4 is different from the second direction D2. An included angle between the third direction D3 and the fourth direction D4 is, for example, greater than or equal to 75 degrees and less than or equal to 105 degrees.

The first airflow F1 is turned at least once by the first air guide duct 360 to flow to the first gap G1 along the third direction D3. The second airflow F2 is turned at least once by the second air guide duct 370 to flow to the second gap G2 along the fourth direction D4. In addition, in the embodiment, in order to achieve a good heat dissipation effect, the optical engine module 300a of the embodiment further includes a first heat exchange module 380a and a second heat exchange module 385a. As shown in FIG. 1A, FIG. 1B and FIG. 1C, the first airflow F1 provided by the first air outlet E11 of the fan module 350a flows through the transmissive light valve 320 in a vertical direction (i.e., the third direction D3) to increase a temperature, and then exchanges heat with the first heat exchange module 380a to reduce the temperature, and then is sucked into the fan module 350a again to circulate; while, the second airflow F2 provided by the second air outlet E12 of the fan module 350a flows through the transmissive light valve 320 in a horizontal direction (i.e., the fourth direction D4) to increase the temperature, and then exchanges heat with the second heat exchange module 385a to cool down, and is then sucked into the fan module 350a again to circulate. In this way, a cooling cycle inside the optical engine module 300a may be completed, thereby dissipating the heat of the transmissive light valve 320.

In detail, the first heat exchange module 380a is fixed to the housing 310 (shown in FIG. 1A), and at least a part of the first heat exchange module 380a is located in the first inner circulation zone S1. The second heat exchange module 385a is fixed to the housing 310 (shown in FIG. 1B), and at least a part of the second heat exchange module 385a is located in the second inner circulation zone S2. The housing 310, the first heat exchange module 380a, the second heat exchange module 385a, and a part of the lens module 400 define a sealed cavity SC, which has a dustproof effect. In other words, the optical engine module 300a of the embodiment may be regarded as a closed optical engine design, i.e., the airflows inside and outside the optical engine module 300a are isolated from each other. In an embodiment, each of the first heat exchange module 380a and the second heat exchange module 385a includes one of a heat sink, a heat conductive substrate, a heat pipe, a cooling chip, or a combination thereof.

For example, referring to FIG. 1B and FIG. 2A at the same time, each of the first heat exchange module 380a and the second heat exchange module 385a may be, for example, a heat sink 382 having double-sided heat dissipation fins 382a and 382b. The double-sided heat dissipation fins 382a and 382b are, for example, respectively arranged on both sides of a heat dissipation substrate I. The heat dissipation substrate I is fixed on the housing 310, the heat dissipation fins 382a are arranged in the accommodating space S, and the heat dissipation fins 382b are arranged outside the accommodating space S. Alternatively, referring to FIG. 1B and FIG. 2B at the same time, each of the first heat exchange module 380a and the second heat exchange module 385a may be, for example, a heat dissipation module having heat dissipation fins 382c, 382d, a heat conductive substrate 384 and a heat pipe 386, wherein one side of the heat conductive substrate 384 is directly connected to the heat dissipation substrate I of the heat dissipation fins 382c, and the other side of the heat conductive substrate 384 is connected to the heat dissipation fins 382d through the heat pipe 386. Alternatively, referring to FIG. 1B and FIG. 2C at the same time, the first heat exchange module 380a may also be a local enhanced cooling type internal and external heat exchange module having the heat dissipation fins 382c, 382d, the heat conductive substrate 384, the heat pipe 386 and a cooling chip 388, wherein two opposite sides of the cooling chip 388 are respectively connected to the heat dissipation substrate I of the heat dissipation fins 382c and the heat conductive substrate 384, and the heat conductive substrate 384 is connected to the heat dissipation fins 382d through the heat pipe 386.

In short, the optical engine module 300a of the embodiment is a closed internal circulation cooling design, which implements internal circulation on the optical engine module 300a through a cooling fan (i.e., the fan module 350a) having two air outlets. The first gap G1 is formed between the focusing lens 330 and the transmissive light valve 320, and the second gap G2 is formed between the transmissive light valve 320 and the optical sheet 340. The first air outlet E11 and the second air outlet E12 of the fan module 350a are respectively connected to the first air guide duct 360 and the second air guide duct 370, and the first air guide duct 360 and the second air guide duct 370 respectively guide the first airflow F1 and the second airflow F2 to the first gap G1 and the second gap G2, which are approximately vertically staggered in design. In this way, the cooling capacity inside the optical engine module 300a may be enhanced to achieve a good heat dissipation effect, thereby improving the brightness. In addition, the projection device 100a using the optical engine module 300a of the embodiment may have great imaging quality.

Other embodiments are listed below for illustration. It should be noticed that reference numbers of the components and a part of contents of the aforementioned embodiment are also used in the following embodiment, wherein the same reference numbers denote the same or like components, and descriptions of the same technical contents are omitted. The aforementioned embodiment may be referred for descriptions of the omitted parts, and detailed descriptions thereof are not repeated in the following embodiment.

FIG. 3A is a schematic three-dimensional view of a projection device according to another embodiment of the disclosure. FIG. 3B is a schematic view of the projection device of FIG. 3A. FIG. 3C is another schematic view of the projection device of FIG. 3A. FIG. 3D is a schematic cross-sectional view along a line I-I of FIG. 3B. FIG. 3E is a schematic cross-sectional view along a line II-II of FIG. 3C. FIG. 3F is a schematic diagram of relative positions of the fan module, the first gap and the second gap in FIG. 3A. It should be noted that, for the convenience of explanation and clarity, some components such as the housing, the casing, etc. are omitted in FIG. 3B and FIG. 3C, FIG. 3F shows a fan module 350b and the transmissive light valve 320 on a same plane, and the coordinate axis is based on the transmissive light valve 320.

Referring to FIG. 1A, FIG. 1B, FIG. 3A, FIG. 3B, FIG. 3C, FIG. 3D and FIG. 3E at the same time, a projection device 100b of the embodiment is similar to the projection device 100a described above, and a main difference there between is that: in the embodiment, the fan module 350b of an optical engine module 300b includes a first cooling fan 352 and a second cooling fan 354, which means that the fan module 350b of the embodiment includes two independent cooling fans. The first cooling fan 352 is disposed in a first inner circulation zone S1′ (as shown in FIG. 3D) and has a first air outlet E21, and the second cooling fan 354 is disposed in a second inner circulation zone S2′(as shown in FIG. 3E) and has a second air outlet E22. Here, the first cooling fan 352 and the second cooling fan 354 are respectively, for example, blower fans, but the disclosure is not limited thereto. The first inner circulation zone S1′ and the second inner circulation zone S2′ in the housing 310 are gas-isolated from each other (as shown in FIG. 3D and FIG. 3E), i.e., the first inner circulation zone S1′ and the second inner circulation zone S2′ are two closed zones, and the first airflow F1 and the second airflow F2 therein do not interfere with each other.

In detail, the first inner circulation zone S1′ and the second inner circulation zone S2′ respectively have the first cooling fan 352 and the second cooling fan 354, and the first cooling fan 352 and the second cooling fan 354 are respectively connected to the first gap G1 and the second gap G2 through the curved first air guide duct 360 and the second air guide duct 370, and the first airflow F1 and the second airflow F2 are respectively deflected and blown into the first gap G1 and the second gap G2 through the first air guide duct 360 and the second air guide duct 370. Since the first air guide duct 360 and the second air guide duct 370 have curved ducts with arc structures and have a flow channel design with tapered diameters, a flow resistance on the air output by the first cooling fan 352 and the second cooling fan 354 that turns and enters the smaller first gap G1 and second gap G2 may be effectively reduced. A normal direction of the second port 364 of the first air guide duct 360 is the third direction D3 (parallel to the Y direction). A normal direction of the fourth port 374 of the second air guide duct 370 is the fourth direction D4 (antiparallel to the X direction). An included angle between the third direction D3 and the first direction D1 (antiparallel to a Z direction) is, for example, greater than or equal to 75 degrees and less than or equal to 105 degrees, such as 90 degrees. An included angle between the fourth direction D4 and the second direction D2 (parallel to the Z direction) is, for example, greater than or equal to 75 degrees and less than or equal to 105 degrees. An included angle between the third direction D3 and the fourth direction D4 is, for example, greater than or equal to 75 degrees and less than or equal to 105 degrees, which means that the first direction D1 is antiparallel to the second direction D2.

The first airflow F1 is located upstream of the optical path of the transmissive light valve 320 (such as the side of the light incident surface of the transmissive light valve 320), while the second airflow F2 is located downstream of the optical path of the transmissive light valve 320 (such as the side of the light emitting surface of the transmissive light valve 320), and a flow field of the first airflow F1 does not interfere with a flow field of the second airflow F2, which may avoid vortex and noise generated by the flow fields in different directions. The first airflow F1 and the second airflow F2 leaving the first gap G1 and the second gap G2 respectively circulate toward the upstream and downstream of the optical path of the transmissive light valve 320.

Generally, when a fan blows air, pressures and flow rates at different positions will be different due to a rotation direction of fan blades. According to the rotation direction of the fan blades, an air outlet of the fan may produce a low-pressure zone with a high flow rate (high flow volume) and a high-pressure zone with a low flow rate (low flow volume), so that an air outlet volume is distributed in a trapezoidal shape. For example, referring to FIG. 3F, the fan blades of one of the first cooling fan 352 and the second cooling fan 354 rotate clockwise A, while the fan blades of the other one of the first cooling fan 352 and the second cooling fan 354 rotate counterclockwise B. Here, the first cooling fan 352 rotates clockwise A, and the second cooling fan 354 rotates counterclockwise B, but the disclosure is not limited thereto. A long side of the first air outlet E21 has a first air outlet end E21a and a second air outlet end E21b, wherein an air outlet volume of the first air outlet end E21a is greater than an air outlet volume of the second air outlet end E21b, and the second air outlet end E21b is closer to the second inlet terminal G21 of the second gap G2 than the first air outlet end E21a. A long side of the second air outlet E22 has a first air outlet end E22a and a second air outlet end E22b, wherein an air outlet volume of the first air outlet end E22a is greater than that of the second air outlet end E22b, and the second air outlet end E22b is closer to the first inlet terminal G11 of the first gap G1 than the first air outlet end E22a.

The above configuration is to allow the transmissive light valve 320 to have a more uniform temperature distribution, so that the first air outlet end E21a of the first air outlet E21 of a high-flow rate low-pressure zone L1 is closer to an outlet end of the second gap G2, and the first air outlet end E22a of the second air outlet E22 of a high-flow rate low-pressure zone L2 is closer to an outlet end of the first gap G1, so that four corners of the transmissive light valve 320 in FIG. 3F have the best cooling capacity of the first cooling fan 352 and the worst cooling capacity of the second cooling fan 354 at the lower left corner; and have the best cooling capacity of the second cooling fan 354 and the worst cooling capacity of the first cooling fan 352 at the upper right corner. The lower right corner of the transmissive light valve 320 is located at a position where the airflow volumes of the first cooling fan 352 and the second cooling fan 354 are both low, i.e., low-flow rate high-pressure zones H1 and H2, but is also the position of the inlet ends of the first gap G1 and the second gap G2; the upper left corner of the transmissive light valve 320 is located at a position where the airflow volumes of the first cooling fan 352 and the second cooling fan 354 are relatively high, namely, i.e., the high-flow rate low-pressure zones L1 and L2, but it is also the position of the outlet ends of the first gap G1 and the second gap G2 (i.e., the position where the air temperature is relatively high). The above-mentioned flow field distribution may reduce the temperature of the transmissive light valve 320, and may also make a temperature design of the entire transmissive light valve 320 as uniform as possible.

Furthermore, the optical engine module 300b of the embodiment further includes a focusing lens 335 (shown in FIG. 3E) disposed upstream of the optical path of the optical sheet 340, wherein the second airflow F2 flows between the transmissive light valve 320 and the optical sheet 340, and also flows between the optical sheet 340 and the focusing lens 335. As shown in FIG. 3A, the optical engine module 300b of the embodiment further includes a casing 315, wherein the casing 315 has a containing space C. The optical engine module 300b and at least a part of the lens module 400 are disposed in the containing space C, wherein the containing space C and the accommodating space S′ of the optical engine module 300b are gas-isolated from each other. Namely, the first airflow F1 and the second airflow F2 in the first inner circulation zone S1′ and the second inner circulation zone S2′ will not flow into the containing space C, i.e., they will not circulate with the containing space C. In an embodiment, the projection device 100a may selectively include a light converging element 500, such as a light funnel or a focusing lens, the light converging element 500 is, for example, disposed in the accommodating space S′ and configured to focus the light beam of the light-emitting element 200a to the transmissive light valve 320.

In order to achieve a good heat dissipation effect, the optical engine module 300b of the embodiment may further includes a first system fan 395 and a second system fan 397. The first system fan 395 is disposed in the containing space C and is relatively adjacent to the first inner circulation zone S1′. The second system fan 397 is disposed in the containing space C and is relatively adjacent to the second inner circulation zone S2′. The airflows F of the first system fan 395 and the second system fan 397 outside the first inner circulation zone S1′ and the second inner circulation zone S2′ are both designed to blow outward, i.e., the generated airflow may flow outside the containing space C.

Moreover, a first heat exchange module 380b of the optical engine module 300b of the embodiment is disposed in the containing space C and includes heat dissipation fins 382e, a heat conductive substrate 384b and a heat pipe 386b. The heat pipe 386b connects the heat dissipation fins 382e and the heat conductive substrate 384b, and the heat conductive substrate 384b is connected to the housing 310, and the first system fan 395 is disposed at one side of the heat dissipation fins 382e. In addition, the optical engine module 300b of the embodiment further includes a light source heat dissipation module 390, which is disposed in the containing space C and includes a light source heat conduction member 392 and a heat exchange element 394. One end of the light source heat conduction member 392 may be connected to the light source module 200 via, for example, a thermal interface material (TIM) (not shown), wherein the light source heat conduction member 392 connects the light source module 200 and the heat exchange element 394, the second system fan 397 is disposed at one side of the heat exchange element 394, and the airflow generated by the second system fan 397 flows through the heat exchange element 394 and the second heat exchange module 385b.

In short, in the embodiment, cooling fans (i.e., the first cooling fan 352 and the second cooling fan 354) are respectively used on the light emitting surface and the light incident surface of the transmissive light valve 320, which may effectively improve the heat dissipation capability of the transmissive light valve 320. Through the transmissive light valve 320, the housing 310 of the optical engine module 300b is divided into two independent and closed first inner circulation zone S1′ and second inner circulation zone S2′, so that the airflows of the first cooling fan 352 and the second cooling fan 354 respectively located in the first inner circulation zone S1′ and the second inner circulation zone S2′ will not interfere with each other to increase the flow resistance. In addition, the first cooling fan 352 and the second cooling fan 354 respectively rotate clockwise A and counterclockwise B, thereby uniformly distributingthe flow field passing through the transmissive light valve 320 to provide a uniform temperature of the transmissive light valve 320. In addition, it may be learned through simulation that, compared with the existing art of using unidirectional cooling, the staggered bidirectional cooling method in the embodiment may effectively reduce a temperature of a center point of the transmissive light valve 320 by another 8° C., and a temperature difference between the center point and the corner of the transmissive light valve 320 may also be reduced from 17° C. to 13° C. (i.e., a further reduction of 4° C.), which may have a great heat dissipation effect.

In summary, the embodiments of the disclosure have at least one of following advantages or effects. In the design of the optical engine module of the disclosure, the transmissive light valve divides the accommodating space into a first inner circulation zone and a second inner circulation zone, wherein a first airflow is provided to a first gap between the focusing lens and the transmissive light valve via a first air outlet of the fan module, and a second airflow is provided to a second gap between the transmissive light valve and the optical sheet via a second air outlet of the fan module, and the first direction is different from the second direction. In this way, the cooling capacity inside the optical engine module may be enhanced, and a great heat dissipation effect is achieved, thereby improving the brightness. In addition, the projection device using the optical engine module of the disclosure may have a great imaging quality.

The foregoing description of the preferred embodiments of the disclosure has been presented for purposes of illustration and description. It is not intended to be exhaustive or to limit the disclosure to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the disclosure and its best mode practical application, thereby to enable persons skilled in the art to understand the disclosure for various embodiments and with various modifications as are suited to the particular use or implementation contemplated. It is intended that the scope of the disclosure be defined by the claims appended hereto and their equivalents in which all terms are meant in their broadest reasonable sense unless otherwise indicated. Therefore, the term “the disclosure”, “the disclosure” or the like does not necessarily limit the claim scope to a specific embodiment, and the reference to particularly preferred exemplary embodiments of the disclosure does not imply a limitation on the disclosure, and no such limitation is to be inferred. The disclosure is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the disclosure. It should be appreciated that variations may be made in the embodiments described by persons skilled in the art without departing from the scope of the disclosure as defined by the following claims. Moreover, no element and component in the disclosure is intended to be dedicated to the public regardless of whether the element or component is explicitly recited in the following claims.

What is claimed is:

1. An optical engine module, for connecting to a lens module, the optical engine module comprising a housing, a transmissive light valve, a focusing lens, an optical sheet, and a fan module, wherein
the housing has an accommodating space and is connected to the lens module;
the transmissive light valve is disposed in the accommodating space, wherein the transmissive light valve divides the accommodating space into a first inner circulation zone and a second inner circulation zone;
the focusing lens is disposed in the first inner circulation zone, and a first gap is formed between the focusing lens and the transmissive light valve;
the optical sheet is disposed in the second inner circulation zone, and the transmissive light valve is located between the focusing lens and the optical sheet, wherein a second gap is formed between the transmissive light valve and the optical sheet; and
the fan module is disposed in the housing, the fan module has a first air outlet and a second air outlet, the fan module provides a first airflow to the first gap through the first air outlet, the fan module provides a second airflow to the second gap through the second air outlet, wherein a normal direction of the first air outlet is a first direction, a normal direction of the second air outlet is a second direction, and the first direction is different from the second direction.

2. The optical engine module according to claim 1, wherein the first direction is antiparallel to the second direction.

3. The optical engine module according to claim 1, wherein the optical engine module further comprises a first air guide duct and a second air guide duct, wherein:
the first air guide duct has a first port and a second port, the first port is connected to the first air outlet, and the second port is connected to a first inlet terminal of the first gap; and
the second air guide duct has a third port and a fourth port, the third port is connected to the second air outlet, and the fourth port is connected to a second inlet terminal of the second gap.

4. The optical engine module according to claim 3, wherein a normal direction of the second port of the first air guide duct is a third direction, a normal direction of the fourth port of the second air guide duct is a fourth direction, an included angle between the third direction and the first direction is greater than or equal to 75 degrees and less than or equal to 105 degrees, an included angle between the fourth direction and the second direction is greater than or equal to 75 degrees and less than or equal to 105 degrees, and an included angle between the third direction and the fourth direction is greater than or equal to 75 degrees and less than or equal to 105 degrees.

5. The optical engine module according to claim 4, wherein the first airflow is turned at least once through the first air guide duct to flow to the first gap along the third direction, and the second airflow is turned at least once through the second air guide duct to flow to the second gap along the fourth direction.

6. The optical engine module according to claim 3, wherein one of the second port of the first air guide duct and the fourth port of the second air guide duct is located at one side of a long side of the transmissive light valve, and the other one of the second port of the first air guide duct and the fourth port of the second air guide duct is located at one side of a short side of the transmissive light valve, and the long side of the transmissive light valve is connected to the short side.

7. The optical engine module according to claim 1, wherein the fan module comprises a first cooling fan and a second cooling fan, the first cooling fan has the first air outlet, and the first air outlet is located in the first inner circulation zone, and the second cooling fan has the second air outlet, and the second air outlet is located in the second inner circulation zone, and the first inner circulation zone and the second inner circulation zone are gas-isolated from each other.

8. The optical engine module according to claim 7, wherein the first cooling fan and the second cooling fan respectively comprise a blower fan.

9. The optical engine module according to claim 7, wherein a long side of the first air outlet has a first air outlet end and a second air outlet end, an air outlet volume of the first air outlet end is greater than an air outlet volume of the second air outlet end, and the first air outlet end is closer to an outlet end of the second gap than the second air outlet end.

10. The optical engine module according to claim 7, wherein a long side of the second air outlet has a first air outlet end and a second air outlet end, an air outlet volume of the first air outlet end is greater than an air outlet volume of the second air outlet end, and the first air outlet end is closer to an outlet end of the first gap than the second air outlet end.

11. The optical engine module according to claim 7, wherein fan blades of one of the first cooling fan and the second cooling fan rotate clockwise, and the fan blades of the other one of the first cooling fan and the second cooling fan rotate counterclockwise.

12. The optical engine module according to claim 1, wherein the first airflow is located upstream of the transmissive light valve, and the second airflow is located downstream of the transmissive light valve, and a flow field of the first airflow does not interfere with a flow field of the second airflow.

13. The optical engine module according to claim 1, wherein the optical engine module further comprises a first heat exchange module and a second heat exchange module, wherein:
the first heat exchange module is fixed to the housing, and at least a part of the first heat exchange module is located in the first inner circulation zone; and
the second heat exchange module is fixed to the housing, and at least a part of the second heat exchange module is located in the second inner circulation zone, wherein the housing, the first heat exchange module, the second heat exchange module and a part of the lens module define a sealed cavity.

14. The optical engine module according to claim 13, wherein each of the first heat exchange module and the second heat exchange module comprises one of heat dissipation fins, a heat conductive substrate, a heat pipe, a cooling chip, or a combination thereof.

15. The optical engine module according to claim 1, wherein the optical engine module further comprises a casing, wherein:
the casing has a containing space, the optical engine module and the lens module are arranged in the containing space, wherein the containing space and the optical engine module are gas-isolated from each other.

16. The optical engine module according to claim 15, wherein the optical engine module further comprises a first system fan and a second system fan, wherein:
the first system fan is disposed in the containing space, and is adjacent to the first inner circulation zone; and
the second system fan is disposed in the containing space, and is adjacent to the second inner circulation zone.

17. The optical engine module according to claim 16, wherein the optical engine module further comprises a first heat exchange module, wherein:
the first heat exchange module is arranged in the containing space, and comprises heat dissipation fins, a heat pipe and a heat conductive substrate, the heat pipe connects the heat dissipation fins and the heat conductive substrate, and the heat conductive substrate is connected to the housing, and the first system fan is arranged on one side of the heat dissipation fins.

18. A projection device, comprising a light source module, an optical engine module and a lens module, wherein
the light source module is configured to provide an illumination beam;
the optical engine module comprises a housing, a transmissive light valve, a focusing lens, an optical sheet, and a fan module, wherein
the housing has an accommodating space;
the transmissive light valve is disposed in the accommodating space, and is located in a transmission path of the illumination beam, and is configured to convert the illumination beam into an image beam, wherein the transmissive light valve divides the accommodating space into a first inner circulation zone and a second inner circulation zone;
the focusing lens is disposed in the first inner circulation zone, and a first gap is formed between the focusing lens and the transmissive light valve;
the optical sheet is disposed in the second inner circulation zone, and the transmissive light valve is located between the focusing lens and the optical sheet, wherein a second gap is formed between the transmissive light valve and the optical sheet; and
the fan module is disposed in the housing, the fan module has a first air outlet and a second air outlet, the fan module provides a first airflow to the first gap through the first air outlet, the fan module provides a second airflow to the second gap through the second air outlet, wherein a normal direction of the first air outlet is a first direction, a normal direction of the second air outlet is a second direction, and the first direction is different from the second direction; and
the lens module is connected to the housing, and is disposed in a transmission path of the image beam, a part of the lens module is disposed in the housing, and the lens module is configured to project the image beam out of the projection device.
